(19) United States
(12) Patent Application Publication
(10) Pub. No.: US 2006/0125577 A1
(43) Pub. Date: Jun. 15, 2006

(54) Acoustic resonator device and method for manufacturing the same

(75) Inventors: Chin-Tang Hsieh, Kaohsiung City (TW); Ying-Chung Chen, Kaohsiung City (TW); Sean Wu, Tainan City (TW); Chen-Kuei Chung, Tainan City (TW); Kuo-Sheng Kao, Chiayi City (TW); Chin-Chi Chen, Kaohsiung (TW)

Correspondence Address: TROXELL LAW OFFICE PLLC;SUITE 1404, 5205 LEESBURG PIKE, FALLS CHURCH, VA, 22041, US

(73) Assignee: International Semiconductor Techonology Ltd.

(21) Appl. No.: 11/008,930

(22) Filed: Dec. 13, 2004

(51) Int. Cl. H03H 9/56

(52) U.S. Cl. 333/191

(57) ABSTRACT

An acoustic resonator device includes a semiconductor substrate, a FBAR (thin film bulk acoustic resonator) and a support plate. The FBAR is fabricated on the upper surface of the semiconductor substrate. The semiconductor substrate has a resonant cavity through the upper and the lower surfaces thereof. The support plate is attached to the lower surface of the semiconductor substrate to shelter the opening of the resonant cavity. Moreover, the support plate can provide a larger die-attaching area for the acoustic resonator device, for the protection of the resonant cavity from chipping during wafer sawing.

### FIELD OF THE INVENTION

The present invention relates to an acoustic resonator device, more particularly to thin film bulk acoustic resonator (FBAR) and method for manufacturing the same.

### BCAKGROUND OF THE INVENTION

Generally, known filters for electronic circuits, such as FBARs (thin film bulk acoustic resonators), enable to be fabricated in mass production on a semiconductor substrate (like wafer) utilizing micro-electromechanical fabricating processes. FBARs have a piezoelectric thin film on a cavity to generate acoustic resonance, with specific resonant frequency so as to permit the passage of a specific frequent wave and to intercept other frequent waves. FARs can be mounted to an electronic device to receive or emit wave with a specific frequency. Basically, the known FBARs are fabricated on a semiconductor wafer with resonant cavities or depressions to constitute an acoustic resonator device.

Several known types of acoustic resonator devices are disclosed in R.O.C. Taiwan Patent publication No. 514,621. Referring to FIG. 1, a known acoustic resonator device 100 comprises a FBAR 110 and a semiconductor substrate 120 such as a silicon substrate. The FBAR 110 is fabricated on the upper surface of the semiconductor substrate 120 and consists of an upper electrode 111, a lower electrode 112 and a layer of piezoelectric material 113 positioned between the upper electrode 111 and the lower electrode 112. The semiconductor substrate 120 has a resonant cavity 121 through the upper and lower surfaces to suspend the FBAR 110 in the air. A lots of semiconductor substrates 120 before sawing are integrally formed on a semiconductor wafer with a large dimension in order to mass-produce the acoustic resonator devices 100 through MEMS processes. However, sawing a semiconductor wafer to individual dices (semiconductor substrates 120) encounters a chipping problem due to the resonant cavities 121 in the semiconductor substrates 120. The semiconductor substrate 120 is easily damaged and generates chipping 122 during wafer sawing processes. Besides, the exposed resonant cavity 121 is easily contaminated by die-attaching adhesive for fixing the acoustic resonator device 100, and the increase of the bonding strength is quite limited.

Referring to FIG. 2, another known acoustic resonator device 200 includes a FBAR 210 and a semiconductor (silicon) substrate 220. Likewise, the FBAR 210 has an upper electrode 211, a lower electrode 212 and a piezoelectric material layer 213 positioned between the upper electrode 211 and the lower electrode 212. The FBAR 210 is fabricated on the upper surface 221 of the semiconductor substrate 220 and has a plurality of etch holes 214 connecting to a depression in the upper surface 221. The resonant cavity 223 of the semiconductor substrate 220 is merely formed by the depression in the semiconductor substrate 220 without penetrating the lower surface 222 of the semiconductor substrate 220 to make the semiconductor substrate 220 with a better supporting strength. Nevertheless, it is obvious that the acoustic resonator device 200 is complicatedly fabricated with a higher cost. Initially, a depression is preformed in the upper surface 221 of the semiconductor substrate 220 by etching to form the resonant cavity 223. Then a sacrificial material such as PSG (phosphor silica glass) is filled into the resonant cavity 223 (not showed in the drawings) and even brim to the upper surface 221 of the semiconductor substrate 220. Therefore the FBAR 210 can be fabricated on the upper surface 221 of the semiconductor substrate 220. Etch holes 214 are formed in the FBAR 210 so that the etching solution can flow into the depression to etch and remove the sacrificial material from the depression. Therefore, the fabricating process is more complicated and the fabricating cost is obviously higher.

### SUMMARY OF THE INVENTION

It is a primary object of the present invention to provide an acoustic resonator device and its fabricating method including a semiconductor substrate, a FBAR (thin film bulk acoustic resonator) and a support plate. The FBAR is fabricated on the upper surface of the semiconductor substrate, and then a resonant cavity is formed through the semiconductor substrate and extends to the FBAR. The support plate is attached to the lower surface of the semiconductor substrate to shelter the resonant cavity so as to enhance the structural strength of the semiconductor substrate. It prevents the semiconductor substrate from chipping during wafer sawing processes, and the support plate also provides a larger die-attaching area without cavity contamination.

It is a secondary object of the present invention to provide a method for fabricating acoustic resonator device. Initially, FBARs are fabricated on the upper surface of a semiconductor substrate in wafer form. The resonant cavity is formed through the semiconductor substrate by etching so that the resonant cavity has an opening on the lower surface. The support plate is attached to the lower surface of the semiconductor substrate to shelter the opening of the resonant cavity. A sawing process is performed to cut the semiconductor substrate and the support plate. Under the protection of the support plate, the semiconductor substrate is free from chipping during the sawing processes. Therefore, the acoustic resonator device with simple fabrication processes of forming resonant cavities can be fabricated at a lower cost.

### DESCRIPTION OF THE DRAWINGS

FIG. 1 is a cross-sectional view of a known acoustic resonator device.

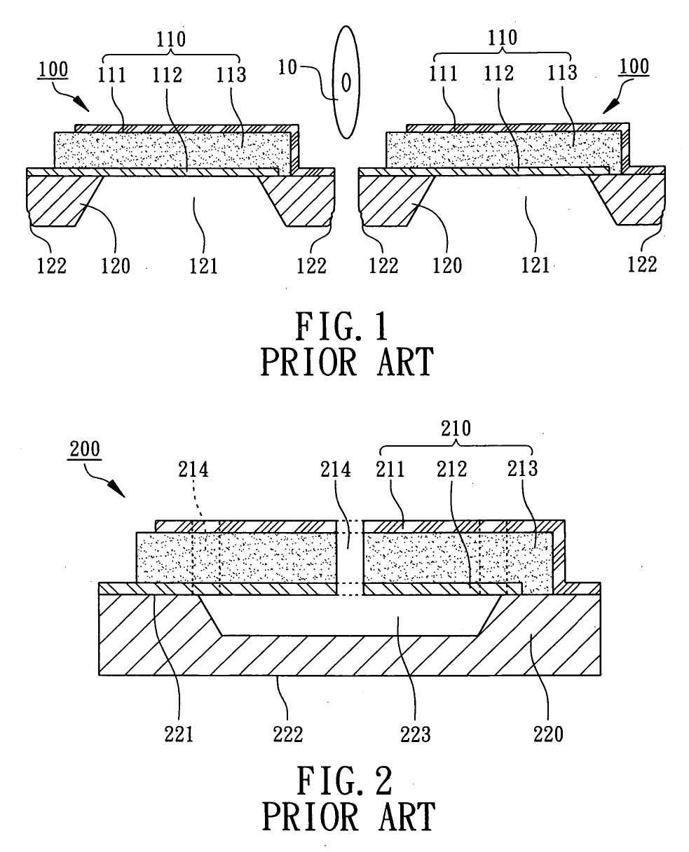

FIG. 2 is a cross-sectional view of another known acoustic resonator device.

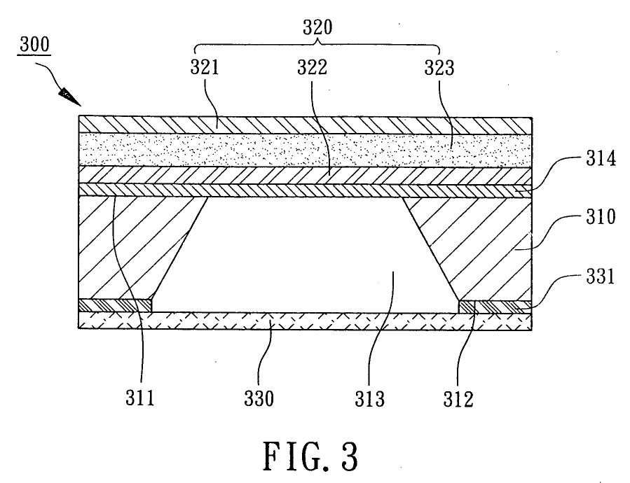

FIG. 3 is a cross-sectional view of an acoustic resonator device in accordance with the embodiment of the present invention.

FIG. 4A to 4D are cross-sectional views of the acoustic resonator device being wafer-level fabricated in accordance with the embodiment of the present invention.

### DETAILED DESCRIPTION OF THE PRESENT INVENTION

Referring to the drawings attached, the present invention is described by means of the embodiment(s) below.

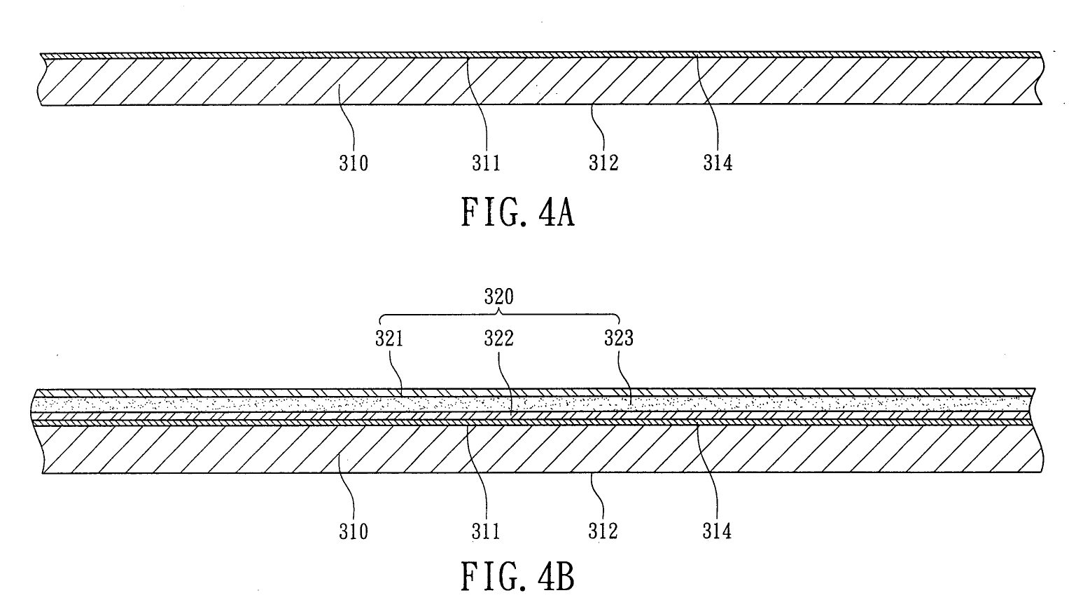

Referring to FIG. 3 an acoustic resonator device 300 mainly includes a semiconductor substrate 310, a FBAR 320 (thin film bulk acoustic resonator) and a support plate 330. The FBAR 320 is positioned above the semiconductor substrate 310, and the support plate 330 is positioned beneath the semiconductor substrate 310. There is a resonant cavity 313 formed in the semiconductor substrate 310 and between the FBAR 320 and the support plate 330. The semiconductor substrate 310 has an upper surface 311 and an opposing lower surface 312. The semiconductor substrate 310 may be made of silicon. The resonant cavity 313 substantially is formed through the semiconductor substrate 310 and extends to the FBAR 320. Etching is performed to form the resonant cavity 313 so that the resonant cavity 313 has an opening on the lower surface 312. In this embodiment, the opening of the resonant cavity 313 on the lower surface 312 is larger than the bottom surface of the resonant cavity 313 on the FBAR 320 in dimension to construct a lower resonant cavity. Normally a silicon nitride layer 314 is formed on the upper surface 311 of the semiconductor substrate 310 to serve as an etching stop layer.

The FBAR 320 is fabricated on the upper surface 311 of the semiconductor substrate 310 and includes an upper electrode 321, a lower electrode 322 and a layer of piezoelectric material 323 between the upper electrode 321 and the lower electrode 322. The upper and lower electrodes 321 and 322 are made of Al, Cu, Pt, Au or Mo, and the piezoelectric material layer 323 may be selected from aluminum nitride, zinc oxide or other piezoelectric materials.

The support plate 330 is attached to the lower surface 312 of the semiconductor substrate 310 to shelter the opening of the resonant cavity 313. The support plate 330 is made of a hard material with the hardness not less than that of the semiconductor substrate 310, such as a ceramic sheet, a silicon sheet or a glass sheet. Preferably, an interface bonding layer 331 such as Cr layer is formed between the lower surface 312 of the semiconductor substrate 310 and the support plate 330 to enhance the bonding strength.

According to the foregoing acoustic resonator device 300, the support plate 330 is attached to the lower surface 312 of the semiconductor substrate 310 so as to shelter the resonant cavity 313 and to enhance the structural strength of the semiconductor substrate 310. The support plate 330 can effectively support the semiconductor substrate 310 from wafer sawing to die attaching, the fabricating processes is illustrated as follows. Therefore, there is no chipping problem on the semiconductor substrate 310. Moreover, the support plate 330 may be reserved as the bottom part of the entire acoustic resonator device 300 for die attachment. The support plate 330 not only provides a larger die attaching area, but also protects the resonant cavity 313 from contamination.

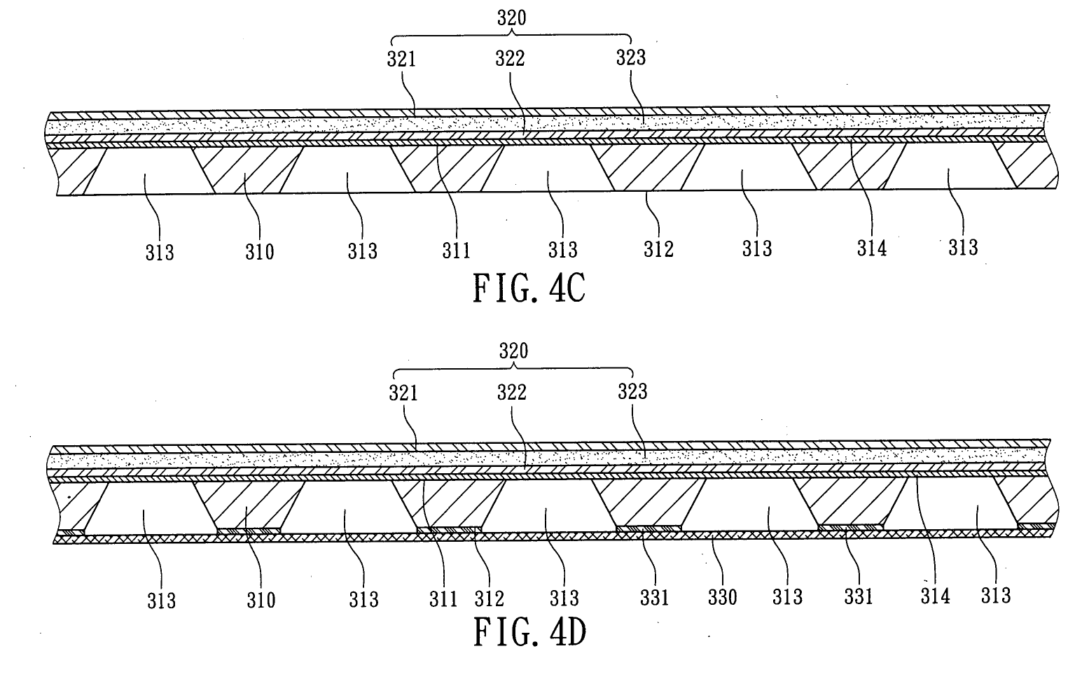

The method for fabricating the acoustic resonator device 300 are illustrated as shown in FIG. 4A to 4D. Initially, at least one of the semiconductor substrate 310 is provided in wafer form, which has an upper surface 311 and a lower surface 312. Next referring to FIG. 4B, the FBAR 320, including an upper electrode 321, a lower electrode 322 and the layer of piezoelectric material 323, is fabricated on the upper surface 311 of the semiconductor substrate 310 by deposition technique or other micro-electromechanical fabricating processes. Next referring to FIG. 4C, a resonant cavity 313 is formed through the semiconductor substrate 310 by dry etching or wet etching from the lower surface 312 to the upper surface 311 (the FBAR 320). After etching, the resonant cavity 313 has an opening on the lower surface 312. Next referring to FIG. 4D, the support plate 330 is attached to the lower surface 312 of the semiconductor substrate 310 so that the opening of the resonant cavity 313 is sheltered. Preferably, the resonant cavity 313 is hermetically sealed by the support plate 330 for a better protection. Next, a wafer-sawing step is performed. In this embodiment, the semiconductor substrate 310 in wafer form and the support plate 330 are cut by a sawing tool to form a plurality of acoustic resonator devices 300 as showed in FIG. 3. The semiconductor substrate 310 is fixed by the support plate 330 to improve structural strength without chipping problems during wafer-sawing processes. Mass production of the acoustic resonator devices 300 can be achieved with a good yield.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A device comprising:
a semiconductor substrate having an upper surface and a lower surface;
a FBAR (thin film bulk acoustic resonator) fabricated on the upper surface of the semiconductor substrate;
a resonant cavity formed through the semiconductor substrate and extending to the FBAR, the resonant cavity having an opening on the lower surface; and
a support plate attached to the lower surface of the semiconductor substrate to shelter the opening of the resonant cavity.

2. The device in accordance with claim 1, wherein the support plate is made of a hard material with the hardness not less than that of the semiconductor substrate.

3. The device in accordance with claim 1, wherein the support plate is selected from the group consisting of a ceramic sheet, a silicon sheet, and a glass sheet.

4. The device in accordance with claim 1, wherein an interface bonding layer is formed between the semiconductor substrate and the support plate.

5. The device in accordance with claim 1, wherein a silicon nitride layer is formed between the semiconductor substrate and the FBAR.

6. The device in accordance with claim 1, wherein the resonant cavity is hermetically sealed by the support plate.

7. A method for fabricating a device comprising:
providing a semiconductor substrate having an upper surface and a lower surface;
fabricating a FBAR (thin film bulk acoustic resonator) on the upper surface of the semiconductor substrate;
forming a resonant cavity through the semiconductor substrate, the resonant cavity having an opening on the lower surface; and
attaching a support plate to the lower surface of the semiconductor substrate to shelter the opening of the resonant cavity.

8. The method in accordance with claim 7, wherein the resonant cavity is formed by etching from the lower surface of the semiconductor substrate.

9. The method in accordance with claim 7, wherein the support plate is made of a hard material with the hardness not less than that of the semiconductor substrate.

10. The method in accordance with claim 7, wherein the support plate is selected from the group consisting of a ceramic sheet, a silicon sheet, and a glass sheet.

11. The method in accordance with claim 7, wherein an interface bonding layer is formed between the semiconductor substrate and the support plate.

12. The method in accordance with claim 7, wherein a silicon nitride layer is formed between the semiconductor substrate and the FBAR.

13. The method in accordance with claim 7, wherein the semiconductor substrate is provided in wafer form, and further comprising the step of sawing the semiconductor substrate and the support plate.
